(19) United States
(12) Patent Application Publication
(10) Pub. No.: US 2016/0068955 A1
(43) Pub. Date: Mar. 10, 2016

(54) HONEYCOMB MULTI-ZONE GAS DISTRIBUTION PLATE

(71) Applicant: Applied Materials, Inc., Santa Clara, CA (US)

(72) Inventors: Paul BRILLHART, Pleasanton, CA (US); Anzhong CHANG, San Jose, CA (US); Edric TONG, Sunnyvale, CA (US); Kin Pong LO, Fremont, CA (US); David K. CARLSON, San Jose, CA (US); Errol Antonio C. SANCHEZ, Tracy, CA (US); Zhiyuan YE, San Jose, CA (US); Satheesh KUPPURAO, San Jose, CA (US)

(21) Appl. No.: 14/822,689

(22) Filed: Aug. 10, 2015

Related U.S. Application Data
(60) Provisional application No. 62/128,731, filed on Mar. 5, 2015.
(60) Provisional application No. 62/047,417, filed on Sep. 8, 2014.

(51) Int. Cl. C23C 16/455; C30B 25/14

(52) U.S. Cl. CPC C23C 16/4557; C30B 25/14

(57) ABSTRACT

Embodiments provided herein generally relate to an apparatus for gas delivering in a semiconductor process chamber. The apparatus may be a gas distribution plate that has a plurality of through holes and a plurality of blind holes formed therein. Process gases are provided into a processing volume of the semiconductor process chamber through the through holes of the gas distribution plate. The blind holes are utilized to control the temperature of the gas distribution plate using a phase change material.

### CROSS-REFERENCE TO RELATED APPLICATIONS

This application claims priority to U.S. Provisional Patent Application Ser. No. 62/047,417, filed on Sep. 8, 2014, and to U.S. Provisional Patent Application Ser. No. 62/128,731, filed Mar. 5, 2015, which herein is incorporated by reference.

### BACKGROUND

1. Field

Embodiments described herein generally relate to apparatus and methods for improving gas distribution in a semiconductor process chamber. More specifically, embodiments described herein relate to a gas distribution plate.

2. Description of the Related Art

In semiconductor processing, various processes are commonly used to form films that have functionality in a semiconductor device. Among those processes are certain types of deposition processes referred to as epitaxy. In an epitaxy process, a gas mixture is typically introduced in a chamber containing one or more substrates on which an epitaxial layer is to be formed. Process conditions are maintained to encourage the vapor to form a high quality material layer on the substrate.

In an exemplary epitaxy process, a material such as a dielectric material or semiconductor material is formed on an upper surface of a substrate. The epitaxy process grows a thin, ultra-pure material layer, such as silicon or germanium, on a surface of the substrate. The material may be deposited in a lateral flow chamber by flowing a process gas substantially parallel to the surface of a substrate positioned on a support, and by thermally decomposing the process gas to deposit a material from the gas onto the substrate surface.

Cross-flow gas delivery apparatuses inject gas into the process chamber such that the gas flows laterally across the surface of the substrate while the substrate is rotated. However, the cross-flow delivery apparatus has limited center to edge tunability since all gases first cross the edge of the substrate. The inlet length of the cross-flow delivery apparatus is very long which causes premature cracking of lower temperature gases such as indium. The long flow path across the substrate in the cross-flow delivery apparatus causes gas by-product mixing during deposition/etching on the surface of the substrate. In some cases, the type and number of precursor species that may be introduced via the cross-flow gas delivery apparatus are limited.

Thus, there is a need in the art for improved gas delivery apparatus.

### SUMMARY

Embodiments provided herein generally relate to an apparatus for gas distribution in a semiconductor process chamber. The apparatus may be a honeycomb gas distribution plate that has a plurality of through holes and a plurality of blind holes formed therein. Process gases are provided into a processing volume of the semiconductor process chamber through the through holes of the gas distribution plate. The blind holes can be utilized to control the temperature of the gas distribution plate.

In one embodiment, a gas distribution plate is disclosed. The gas distribution plate includes a first surface and a second surface. The gas distribution plate further includes a plurality of through holes extending from the first surface to the second surface and a plurality of blind holes partially extending from the first surface.

In another embodiment, a process chamber is disclosed. The process chamber includes one or more walls defining a processing region, and a gas distribution plate located in the processing region. The gas distribution plate includes a first surface and a second surface. The gas distribution plate further includes a plurality of through holes extending from the first surface to the second surface and a plurality of blind holes partially extending from the first surface. The process chamber further includes a substrate support located in the processing region.

In another embodiment, a method for controlling a temperature of a gas distribution plate includes flowing a phase change material into a plurality of blind holes formed in the gas distribution plate, and controlling a pressure inside the blind holes so when the temperature of the gas distribution plate reaches a predetermined level, the phase of the phase change material changes.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A-1B illustrate schematic, cross-sectional views of a process chamber according to various embodiments.

FIGS. 2A-2B illustrate cross-sectional views of a gas distribution plate according to another embodiment.

FIG. 3 illustrates a top view of the gas distribution plate of FIGS. 2A and 2B.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

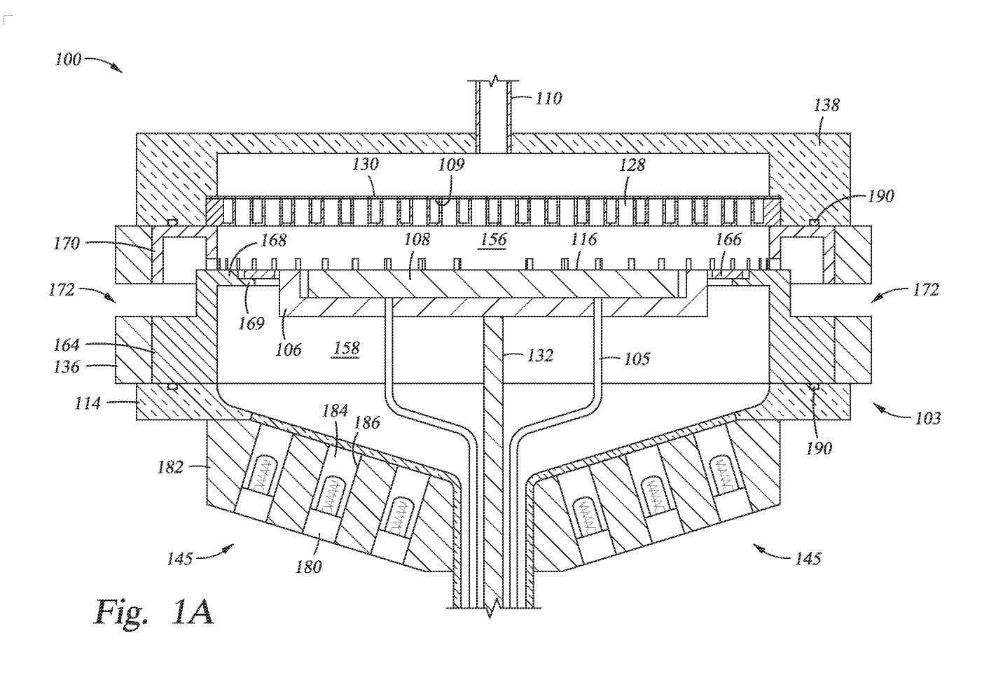

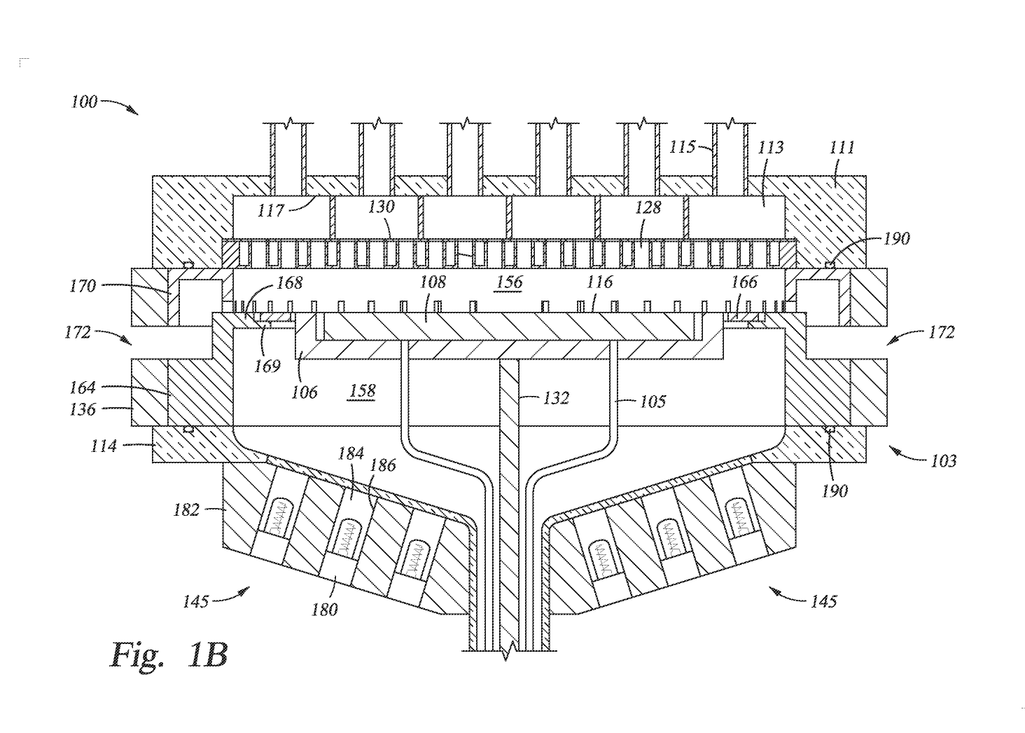

FIG. 1A illustrates a schematic, cross-sectional view of a process chamber 100 according to one embodiment. The process chamber 100 may be used to process one or more substrates, including the deposition of a material on an upper surface 116 of a substrate 108. The process chamber 100 may include a chamber body 103 that may include a lower wall 114, a side wall 136 and an upper wall 138. One or more of walls 114, 136, 138 may define a processing region 156. The upper wall 138 may be made of a reflective material or coated with a reflective material. The lower wall 114 may be transmissive to thermal radiation emitted by a heat source 145, such as a plurality of lamps, and may be transparent to the thermal radiation, defined as transmitting at least 95% of light of a given wavelength or spectrum. Materials useable for the lower wall 114 include quartz and sapphire.

In one embodiment, the lower wall 114 is a quartz dome and is transparent to the emission spectrum of the plurality of lamps. A substrate support 106 may be disposed between the upper wall 138 and the lower wall 114. A lower liner 164 may be coupled to the side wall 136. The lower liner 164 may be formed from quartz, sapphire, or other materials compatible with processing in the chamber and the various process gases. The lower liner 164 may include a ledge 168 extending inward toward the substrate support 106. The ledge 168 may have a recess 169 for receiving an edge ring 166. The edge ring 166 may block a gap between the substrate support 106 and the lower liner 164 to prevent process gases from entering a region 158 defined by the substrate support 106, the lower liner 164 and the lower wall 114.

The substrate 108 may be supported by the substrate support 106, which is supported by a central shaft 132. The substrate support 106 may be disposed in the processing region 156. One or more lift pins 105 may lift the substrate 108 from the substrate support 106 as the substrate support 106 is lowered to a lower position, so the substrate 108 can be moved in and out of the process chamber 100 by a robot (not shown).

A heat source 145, such as an array of heat lamps 180 positioned in a lamphead 182, may be disposed below the lower wall 114 to provide thermal energy to the substrate 108. Words such as below, above, up, down, top, and bottom described herein do not refer to absolute directions, but to directions relative to a basis of the process chamber 100. A cooling channel may be formed in the lamphead 182 for cooling the lamps 180. Each lamp may be positioned in an opening 184 formed in the lamphead 182, and the side walls 186 of the opening 184 may be coated with a reflective material for focusing and/or directing the thermal radiation emitted by the lamps 180.

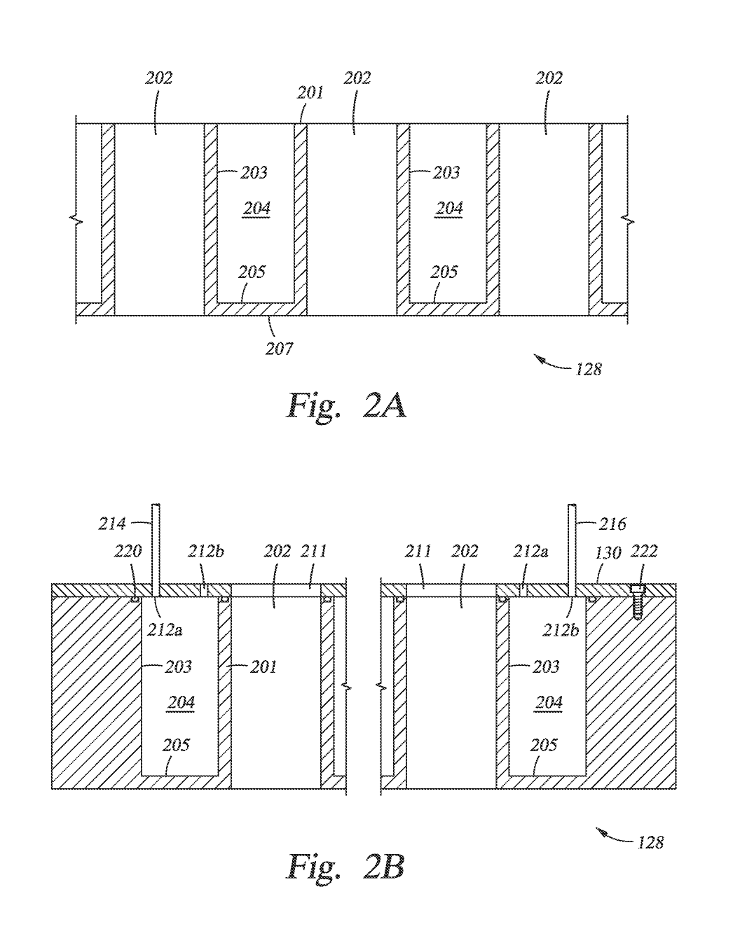

A pumping ring 170 may be disposed on the lower liner 164, and one or more exit ports 172 may be formed between the pumping ring 170 and the lower liner 164. A gas distribution plate 128 may be disposed in the processing region 156. The gas distribution plate 128 may be disposed on the pumping ring 170 and may be secured to the pumping ring 170 by any suitable fastening device, such as bolts or clamps. The gas distribution plate 128 may be made of a heat-resistant and chemical-resistant material, such as quartz or sapphire. An interface plate 130, described in more detail below in connection with FIGS. 2A and 2B, may be disposed on the gas distribution plate 128 for enclosing portions of the gas distribution plate 128. The interface plate 130 may be bolted to the gas distribution plate 128. The interface plate 130 may have a surface 109 facing the gas distribution plate 128 and the surface 109 may be coated with a reflective or absorptive coating, such as a dielectric reflective coating. Seals 190, such as o-rings, may be disposed between the pumping ring 170 and the upper wall 138 and between the lower liner 164 and the lower wall 114.

During operation, one or more process gases may be introduced into the process chamber 100 via a gas feed 110, reaching the upper surface 116 of the substrate 108 through the gas distribution plate 128, and out of the process chamber 100 via the one or more exit ports 172. To promote center-to-edge uniformity, the process gases can reach the center and edge of the upper surface 116 of the substrate 108 at the same time by using the gas distribution plate 128.

FIG. 1B illustrates a schematic, cross-sectional view of the process chamber 100 according to one embodiment. Instead of having an upper wall 138 shown in FIG. 1A, the process chamber 100 may include a structure 111 disposed on the side wall 136 and the pumping ring 170. The structure 111 may include a plurality of compartments 113, and each compartment 113 may include a gas feed 115 for introducing one or more process gases into the processing region 156 via the compartments 113 and the gas distribution plate 128. The structure 111 may be made of a reflective or absorptive material. Alternatively, a surface 117 of the structure 111 facing the gas distribution plate 128 may be coated with a reflective or absorptive material. A single compartment 113 may cover one or more through holes formed in the gas distribution plate 128.

FIGS. 2A and 2B illustrate cross-sectional views of the gas distribution plate 128. As shown in FIG. 2A, the gas distribution plate 128 may include a first surface 201 and a second surface 207 opposite the first surface 201. The gas distribution plate 128 may include a plurality of through holes 202 extending from the first surface 201 to the second surface 207 and a plurality of blind holes 204 that partially extend from the first surface 201 toward the second surface 207. The opening of each through hole 202 and each blind hole 204 may be circular, hexagonal, or any suitable shape. The opening of each through hole 202 may have the same shape as the opening of each blind hole 204, or have a different shape as the opening of each blind hole 204. The process gases flow through the through holes 202 to reach the substrate 108 (FIG. 1). Each blind hole 204 may include side surfaces 203 and a bottom surface 205. The bottom surface 205 may face the upper surface 116 of the substrate 108. The side surfaces 203 and the bottom surface 205 of each blind hole 204 may be coated with a reflective or absorptive material to improve temperature control of the gas distribution plate 128.

During operation, the gas distribution plate 128 may be heated by the heat source 145 (shown in FIG. 1). The process gases flowing into and out of the blind holes 204 provide temperature control of the gas distribution plate 128. The gas distribution plate 128 may be formed by boring the through holes 202 and the blind holes 204 in a solid piece of material, such as a solid piece of quartz material. The gas distribution plate 128 may have a shape that corresponds to the shape of the substrate 108. In one embodiment, the gas distribution plate 128 is circular. The gas distribution plate 128 may have a dimension, such as a diameter, that is greater than the corresponding dimension of the substrate 108. In one embodiment, the substrate 108 is circular and has a diameter or about 300 mm, and the gas distribution plate 128 is also circular and has a diameter of about 400 to 600 mm.

The pattern of the through holes 202 and the blind holes 204 may be configured so the process gases are evenly distributed to the upper surface 116 of the substrate 108 and the layer formed on the upper surface 116 of the substrate 108 is uniform. In one embodiment, the through holes 202 alternate with the blind holes 204 along a linear direction, as shown in FIG. 2A. In one embodiment, the through holes 202 form a plurality of concentric rings, the blind holes 204 form a plurality of concentric rings, and the rings of the through holes 202 and the rings of the blind holes 204 are alternating. One or more temperature sensors, such as pyrometers, (not shown) may be placed inside one or more of the blind holes 204.

FIG. 2B shows the gas distribution plate 128 having the interface plate 130 disposed thereon. The interface plate 130 may be disposed adjacent the first surface 201 of the gas distribution plate 128, and may be fastened to the gas distribution plate 128 by a fastening device 222, such as a bolt, as shown in FIG. 2B. The interface plate 130 may have a plurality of through holes 211, and each through hole 211 is aligned with a through hole 202 of the gas distribution plate 128. Two or more openings 212a, 212b may be formed in the interface plate 130 adjacent each blind holes 204. A phase change material may be flowed into each blind hole 204 via an inlet 214 and a first opening 212a, and out of each blind hole 204 via a second opening 212b and the outlet 216. The blind holes 204 may be in fluid communication with each other by a channel (not shown) formed on the interface plate 130 or by a channel formed in the gas distribution plate 128 around the through holes 202. A pressure control system (not shown) may be employed to control the pressure inside the blind holes 204. The pressure control system may vary the boiling point of the phase change material within each blind hole 204 in order to control the temperature of the gas distribution plate 128. For example, the pressure inside the blind holes 204 may be controlled so the phase change material inside the blind holes 204 will change phase at a predetermined temperature.

As the gas distribution plate 128 reaches the predetermined temperature, the phase change material inside the blind holes 204 changes phase, such as from a liquid to a vapor, which absorbs heat without increase the temperature of the gas distribution plate 128. In this configuration, multiple set-points for the temperature of the gas distribution plate 128 can be achieved by adjusting the pressure of the phase change material, and agile thermal transients may be enabled within the gas distribution plate 128.

Alternatively, a cooling fluid may be circulated through the gas distribution plate 128 via the blind holes 204. The cooling fluid, such as water or helium gas, may be flowed into the blind holes 204 via the inlet 214 and the first opening 212a, and out of the blind holes 204 via the second opening 212b and the outlet 216. The openings 212a, 212b formed in the interface plate 130 may be utilized for fluid communication among the blind holes 204. In another embodiment, the blind holes 204 are in fluid communication with each other via a channel (not shown) formed in the gas distribution plate 128. The channel may be connected to one or more openings (not shown) formed in the side surface 203 and/or the bottom surface 205. A seal 220, such as an o-ring, may be disposed between the gas distribution plate 128 and the interface plate 130 surrounding each blind hole 204.

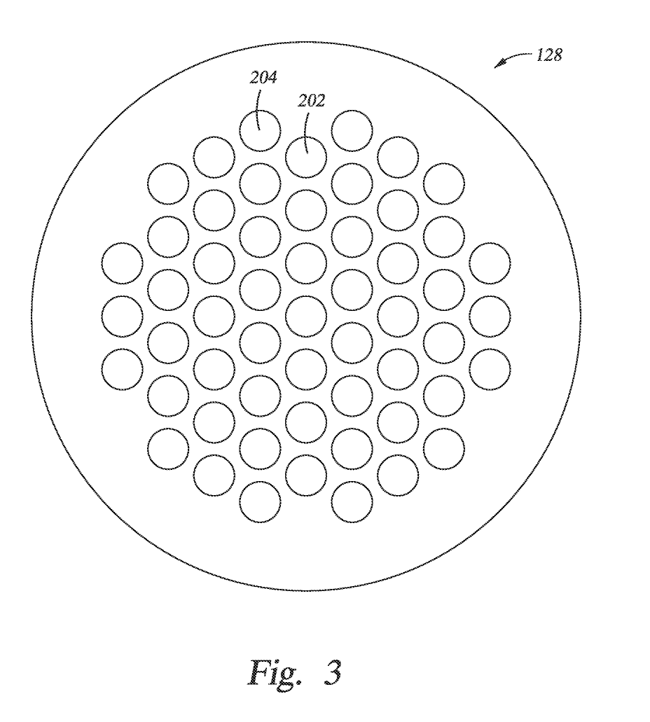

FIG. 3 is a top view of the gas distribution plate 128 according to one embodiment. The gas distribution plate 128 includes the plurality of through holes 202 and the plurality of blind holes 204. As shown in FIG. 3, each opening of the through holes 202 and blind holes 204 has a circular shape. The opening of the through holes 202 and blind holes 204 may have other suitable shapes, such as hexagonal, or a mixture of circular and hexagonal.

The through holes 202 and the blind holes 204 may be formed in the gas distribution plate 128 in any suitable arrangement. In one embodiment, as shown in FIG. 3, the holes 202, 204 have a hexagonal tiling arrangement. The number of holes 202, 204 may be maximized by using a closest packing arrangement of the holes 202, 204. The particular arrangement that achieves closest packing depends on the shape and dimension of the holes 202, 204. For circular holes of similar size, as shown in FIG. 3, it is believed that a hexagonal tiling arrangement achieves a closest packing arrangement. A ratio of total area of through holes 202 to total area of blind holes 204 may be from about 0.5 to about 3.0, such as between about 0.8 to about 2.0, for example about 1.0, depending on the thermal control capability needed for a particular embodiment.

The holes 202, 204 may have any predetermined sizing and spacing. In the embodiment shown in FIG. 3, the holes 202, 204 are circular, with diameter of about 0.5 mm to about 10 mm, such that the holes 202 have the same dimension as the holes 204. The number of holes 202, 204 may be maximized by minimizing the thickness of the wall. In one embodiment, the wall thickness separating two adjacent holes 202, 204 is about 0.5 mm or more. With holes 202, 204 of dimension 1 cm and spacing of about 0.5 mm, a gas distribution plate 128 for processing a 300 mm wafer may have less than 50 to about 300 holes, depending on the size and spacing of the holes, of which 50 to 80% may be through holes 202 and 20 to 50% may be blind holes 204. It should be noted, that a first plurality of the holes 202, 204 may have a first spacing, and a second plurality of the holes 202, 204 may have a second spacing different from the first spacing. The through holes 202 and the blind holes 204 may be staggered, i.e., same type of holes are not adjacent to each other, in order to prevent forming a pattern, such as a racetrack pattern, on the rotating substrate from overly radial gas distribution and/or a radial radiative effect associated with concentric rings of the through holes 202.

In alternate embodiments, the through holes 202, 204 may have different dimensions. For example, providing larger blind holes 204 may enable more robust thermal control of the gas distribution plate 128. Additionally, the through holes 202 may have different dimensions to influence gas flow in different areas of the gas distribution plate 128, if desired. Likewise, the blind holes 204 may have different dimensions to provide more or less thermal control in different areas of the gas distribution plate 128, if desired. Thus, a first plurality of through holes 202 may have a first dimension, while a second plurality of through holes 202 has a second dimension. Similarly, a first plurality of blind holes 204 may have a third dimension and a second plurality of blind holes 204 may have a fourth dimension. In this embodiment, the first, second, third, and fourth dimensions may be the same or different in any desired combination.

While the foregoing is directed to embodiments of the disclosure, other and further embodiments may be devised without departing from the basic scope thereof, and the scope thereof is determined by the claims that follow.

1. A gas distribution plate, comprising:
a first surface; and
a second surface, wherein a plurality of through holes extend from the first surface to the second surface and a plurality of blind holes partially extend from the first surface toward the second surface.

2. The gas distribution plate of claim 1, wherein the through holes and the blind holes have a hexagonal tiling arrangement.

3. The gas distribution plate of claim 2, wherein the through holes and the blind holes are staggered.

4. The gas distribution plate of claim 1, further comprising an interface plate disposed on the gas distribution plate.

5. The gas distribution plate of claim 4, wherein the interface plate has a surface facing the gas distribution plate, and the surface is coated with a reflective or absorptive coating.

6. The gas distribution plate of claim 4, wherein the interface plate includes a plurality of through holes, wherein each through hole of the plurality of through holes of the interface plate is aligned with a through hole of the plurality of through holes in the gas distribution plate.

7. The gas distribution plate of claim 4, wherein the interface plate includes two or more openings adjacent each blind hole in the gas distribution plate.

8. A process chamber, comprising:
one or more walls defining a processing region;
a gas distribution plate located in the processing region, the gas distribution plate comprising:
a first surface; and
a second surface, wherein a plurality of through holes extend from the first surface to the second surface and a plurality of blind holes partially extend from the first surface; and
a substrate support located in the processing region.

9. The process chamber of claim 8, further comprising an interface plate disposed on the gas distribution plate.

10. The process chamber of claim 9, wherein the interface plate is bolted to the gas distribution plate.

11. The process chamber of claim 9, wherein the interface plate has a surface facing the gas distribution plate, and the surface is coated with a reflective or absorptive coating.

12. The process chamber of claim 9, wherein the interface plate includes a plurality of through holes, wherein each through hole of the plurality of through holes of the interface plate is aligned with a through hole of the plurality of through holes in the gas distribution plate.

13. The process chamber of claim 9, wherein the interface plate has two or more openings adjacent each blind hole in the gas distribution plate.

14. The process chamber of claim 8, wherein the one or more walls include an upper wall, a lower wall and a side wall, wherein the substrate support is disposed between the upper wall and the lower wall.

15. The process chamber of claim 8, wherein the one or more walls include a side wall and a lower wall, and the process chamber further comprises a structure disposed on the side wall, wherein the structure includes a plurality of compartments, and wherein each compartment of the plurality of compartments includes a gas feed.

16. The process chamber of claim 15, wherein the structure is made of a reflective or absorptive material.

17. The process chamber of claim 15, wherein the structure includes a surface facing the gas distribution plate, and the surface is coated with a reflective or absorptive material.

18. A method for controlling a temperature of a gas distribution plate, comprising:
flowing a phase change material into a plurality of blind holes formed in the gas distribution plate; and
controlling a pressure inside the plurality of blind holes to change the phase of the phase change material when the temperature of the gas distribution plate reaches a predetermined level.

19. The method of claim 18, wherein the gas distribution plate includes a plurality of through holes.

20. The method of claim 18, wherein an interface plate having two or more openings adjacent each blind hole in the gas distribution plate is disposed on the gas distribution plate.
